(19) United States
(12) Patent Application Publication
(10) Pub. No.: US 2013/0213449 A1
(43) Pub. Date: Aug. 22, 2013

(54) THERMOELECTRIC PLATE AND FRAME EXCHANGER

(71) Applicants: Overton (Bud) Parish, Frisco, TX (US); Joshua E. Moczygemba, Wylie, TX (US)

(72) Inventors: Overton (Bud) Parish, Frisco, TX (US); Joshua E. Moczygemba, Wylie, TX (US)

(73) Assignee: Marlow Industries, Inc., Dallas, TX (US)

(21) Appl. No.: 13/400,416

(22) Filed: Feb. 20, 2012

(51) Int. Cl. H01L 35/30; H01L 35/32; F25B 21/02

(52) U.S. Cl. 136/205; 62/3.2; 136/224

(57) ABSTRACT

An active thermoelectric plate exchanger is provided that includes a plurality of thermally conductive plates and a thermoelectric (TE) assembly having an array of thermoelectric modules (TEM) (e.g., TE coolers or TE generators) for heating/cooling or power generation. For cooling/heating, the TECs actively transfer heat between two fluids. For power generation, the TEGs generate and output power when two fluids having a thermal differential therebetween is applied across the TEGs. Several TE assemblies may be disposed in a stacked configuration between thermally conductive plates contacting the fluids. Additional fluid turbulence generating structures may be included with the fluid flow chambers/paths to generate fluid turbulence and increase thermal efficiency. These structures may include a thermally conductive plate with surface structures or may be a thermally conductive wire cloth, woven wire or wire mesh or screen. The resulting plate exchanger is modular and scalable.

### TECHNICAL FIELD

The present application relates generally to a plate and frame thermal exchanger and, more particularly, to a thermal exchanger having a thermoelectric assembly for enhancing fluid to fluid heat exchange for heating/cooling or power generation.

### BACKGROUND

The main concept behind a heat exchanger is to heat or cool one fluid by transferring heat between it and another fluid. One specific type of heat exchanger is a plate heat exchanger (PHE). In general terms, a plate heat exchanger utilizes metal plates to transfer heat between two fluids. Its major advantage over a conventional heat exchanger (such as shell-and-tube types) is that the working fluids are exposed to a larger surface area with higher heat transfer coefficients due to turbulent flow. This is done in manner that uses less material and space, thus reducing size, weight and cost of a conventional heat exchanger.

Plate heat exchangers are generally designed and suited for transferring heat between medium-pressure and low-pressure fluids. For high-pressure fluids, welded, semi-welded and brazed heat exchangers are typically used. Instead of the conventional shell-and-tube type heat exchanger configuration in which a pipe passes through a thick solid metal chamber, a plate heat exchanger includes two alternating chambers, usually thin in depth, separated at their largest surface by a metal plate (normally corrugated). Stainless steel is a commonly used metal for the plates due to strength (e.g., ability to withstand high temperatures) and corrosion resistance. The plates are typically spaced by sealing gaskets (e.g., rubber) affixed into a section around the plate edges and configured to form an interior volume (or chamber) therebetween through which fluid flows. Channel apertures are formed in the corners of the plates and arranged or configured so that they interlink and form a cold fluid channel between a cold fluid input port and a cold fluid output port. Similarly, the plates are structured, arranged or configured to form a hot fluid channel between hot fluid input and output ports.

Because the plate configuration produces a large surface area and high overall heat transfer coefficients, substantial heat transfer is possible. Having thin chambers between the plates results in a majority of the volume of the fluid contacting the plate surface and increasing heat transfer. As noted, a plate heat exchanger includes a series of relatively thin plates assembled in a rigid frame to form an arrangement of parallel flow channels with alternating hot and cold fluids. In most plate heat exchangers, the surfaces of the plates are corrugated (e.g., intermating or chevron corrugations) which increase heat transfer. The high heat transfer rates resulting from this type of architecture is one of the greatest benefits over traditional shell-and-tube type exchangers.

Exchanger size and weight are important considerations in heat exchanger design. The total rate of heat transfer between the hot and cold fluids passing through a plate heat exchanger is limited by the heat transfer equation: Q=UAΔTm, where U is the overall heat transfer coefficient, A is the total plate area, and ΔTm is the log mean temperature difference. Because of this, it is extremely difficult to increase the thermal efficiency of conventional heat exchangers (such as shell-and-tube types) without significantly increasing exchanger size and weight. For a plate exchanger, heat transfer area is increased by adding more, relatively lightweight, space minimizing panels.

In many thermoelectric cooling and power generation applications, liquid heat exchangers are required. Traditionally, thermoelectric systems have utilized conventional shell-and-tube or multiple cold plate assemblies (such as Lytron Cold Plates) type exchangers. In doing so, they have suffered from excessive weight, cost and reduced performance because they have not been designed into a system utilizing the highest performing heat exchanger technology. Unfortunately, plate exchangers in their traditional plate stacking format do not present a means to integrate with thermoelectric devices.

Therefore, there is a need for a novel plate heat exchanger concept that allows the integration of thermoelectric devices so that the performance of thermoelectric cooling and power generation systems can be maximized while system size, weight and cost metrics are minimized.

### SUMMARY

According to one embodiment, there is provided a thermoelectric plate exchanger for transferring heat between a first fluid and a second fluid. The plate exchanger includes a first outer plate and a second outer plate, a first thermally conductive plate adjacent to and spaced apart from the first outer plate, wherein the first thermally conductive plate and the first outer plate define a first fluid flow chamber, and a second thermally conductive plate adjacent to and spaced apart from the second outer plate, wherein the second thermally conductive plate and the second outer plate define a second fluid flow chamber. A thermoelectric assembly is disposed between, and thermally coupled to, the first thermally conductive plate and the second thermally conductive plate, the thermoelectric assembly includes one or more thermoelectric devices configured to transfer heat from a first side of the thermoelectric device to a second side of the thermoelectric device when a first fluid is present in the first fluid flow chamber and a second fluid is present in the second fluid chamber and a thermal differential exists between the first fluid and the second fluid.

According to another embodiment, there is provided a thermoelectric plate exchanger for generating power. The thermoelectric plate exchanger includes a first outer plate and a second outer plate, and a first thermally conductive plate adjacent to and spaced apart from the first outer plate, wherein the first thermally conductive plate and the first outer plate define a first fluid flow chamber. A first means is disposed within the first fluid flow chamber for generating fluid turbulence within the first fluid flow chamber when a first fluid flows through the first fluid flow chamber. The exchanger further includes a second thermally conductive plate adjacent to and spaced apart from the second outer plate, wherein the second thermally conductive plate and the second outer plate define a second fluid flow chamber. A second means disposed within the second fluid flow chamber for generating fluid turbulence within the second fluid flow chamber when a second fluid flows through the second fluid flow chamber. A thermoelectric assembly is disposed between, and thermally coupled to, the first thermally conductive plate and the second thermally conductive plate, the thermoelectric assembly including one or more thermoelectric devices each operable for transferring heat from a first side of the thermoelectric device to a second side of the thermoelectric device when a first fluid is present in the first fluid flow chamber and a second fluid is present in the second fluid chamber and a thermal differential exists between the first fluid and the second fluid.

Before undertaking the DETAILED DESCRIPTION OF THE INVENTION below, it may be advantageous to set forth definitions of certain words and phrases used throughout this patent document. The term “couple” and its derivatives refer to any direct or indirect communication between two or more elements, whether or not those elements are in physical contact with one another. The terms “include” and “comprise,” as well as derivatives thereof, mean inclusion without limitation. The term “or” is inclusive, meaning and/or. The phrases “associated with” and “associated therewith,” as well as derivatives thereof, may mean to include, be included within, interconnect with, contain, be contained within, connect to or with, couple to or with, be communicable with, cooperate with, interleave, juxtapose, be proximate to, be bound to or with, have, have a property of, or the like. The term “fluid” includes both liquids (e.g., glycol, water) and gases (e.g., air) and combinations of such, unless the term “liquid” or “gas” is specifically used.

### BRIEF DESCRIPTION OF THE DRAWINGS

For a more complete understanding of the present disclosure and its advantages, reference is now made to the following description taken in conjunction with the accompanying drawings, in which like reference numerals represent like parts:

FIG. 1 illustrates a conventional prior art plate heat exchanger;

FIG. 2 is an exploded view of a thermoelectric plate heat exchanger in accordance with one embodiment of the present disclosure;

FIG. 3 illustrates in more detail an example interface plate shown in FIG. 2;

FIGS. 4A and 4B illustrate another embodiment of the interface plate shown in FIG. 2;

FIGS. 5A and 5B illustrate in more detail an example fluid turbulence structure shown in FIG. 2;

FIG. 6 illustrates another embodiment of the fluid turbulence structure;

FIGS. 7A and 7B illustrate a thermoelectric plate heat exchanger (in accordance with the present disclosure) in a cooling/heating application and a thermoelectric plate heat exchanger (in accordance with the present disclosure) in a power generation application; and

FIG. 8 illustrates a basic system for power generation using a thermoelectric plate heat exchanger in accordance with the present disclosure.

### DETAILED DESCRIPTION

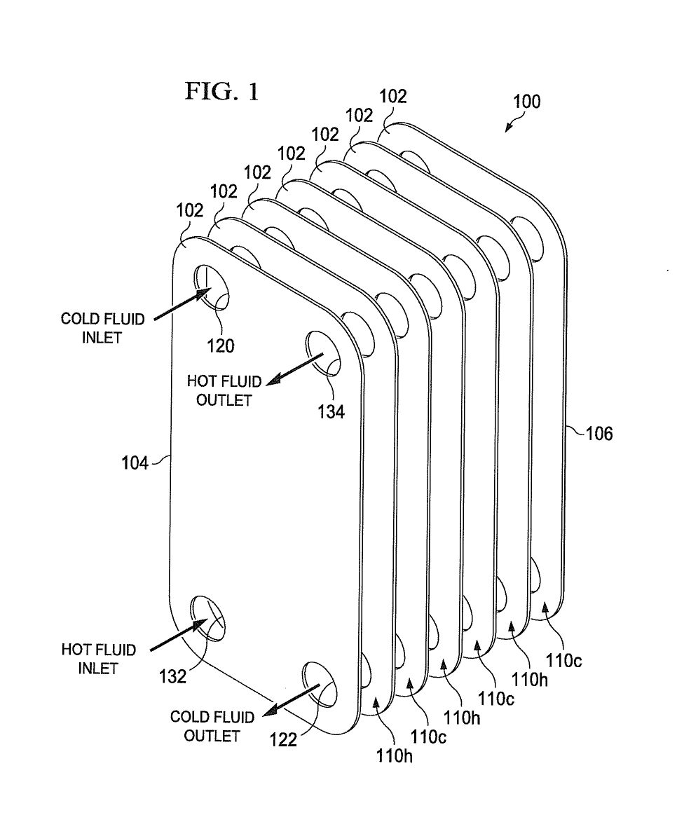

FIGS. 1 through 8, discussed below, and the various embodiments used to describe the principles of the present disclosure in this patent document are by way of illustration only and should not be construed in any way to limit the scope of the disclosure. Those skilled in the art will understand that the principles of the present disclosure may be implemented in any suitably arranged plate heat exchanger. As will be appreciated, though the terms “cooling” or “heating” may be used throughout, these terms also encompass the other term unless the use of the term cooling or heating is expressly and specifically described to only mean cooling or heating, respectively. Further, the term “transfer” when referring to heat transfer includes the transfer of heat in either direction.

Throughout this patent document, the terms thermoelectric (TE), thermoelectric module (TEM), thermoelectric cooler (TEC) and thermoelectric generator (TEG) will have the following general definitions, references or meanings:
Thermoelectric (TE): refers to the thermoelectric effect, materials and/or devices in general;
Thermoelectric module (TEM): a generic term for a device that can perform thermoelectric cooling, thermoelectric heating and/or thermoelectric power generation;
Thermoelectric cooler (TEC): refers to a TEM used as a cooling device;
Thermoelectric heater (TEH): refers to a TEM used as a heating device; and
Thermoelectric generator (TEG): refers to a TEM used as a power generation device.

In most cases, the term “TEC” also refers to a TEM used as either a cooling device or a heating device, and therefore, reference herein to a TEC will include a cooling device and/or a heating device, unless specifically noted or unless it would be clear to one skilled in the art which type of device is intended.

FIG. 1 is a diagram that illustrates a conventional prior art plate heat exchanger (PHE) 100. The PHE 100 includes a plurality of thermally conductive plates 102 positioned adjacent each other and disposed between two outer plates 104, 106. Adjacent and proximate plates each define an interior volume or chamber 110. As shown, the PHE 100 further includes a cold fluid inlet port 120, a cold fluid output port 122, a hot fluid input port 130 and a hot fluid output port 132.

The plates 102, 104, 106 and ports 120, 122, 130, 132 are configured to create a first fluid (cold) channel and a second fluid (hot) channel. The cold fluid channel carries a first fluid from the inlet port 120 through three internal chambers 110c to the outlet port 122. Similarly, the hot fluid channel carries a second fluid from the inlet port 130 through three internal chambers 110h to the outlet port 132. As the two fluids pass through the chambers 110 within the PHE 100, heat is transferred from one fluid to the other fluid. As will be appreciated, gaskets or other structures (not shown) are utilized to configure the path of the two channels between plates. As noted above, the heat transfer capability of the prior art plate heat exchanger is limited.

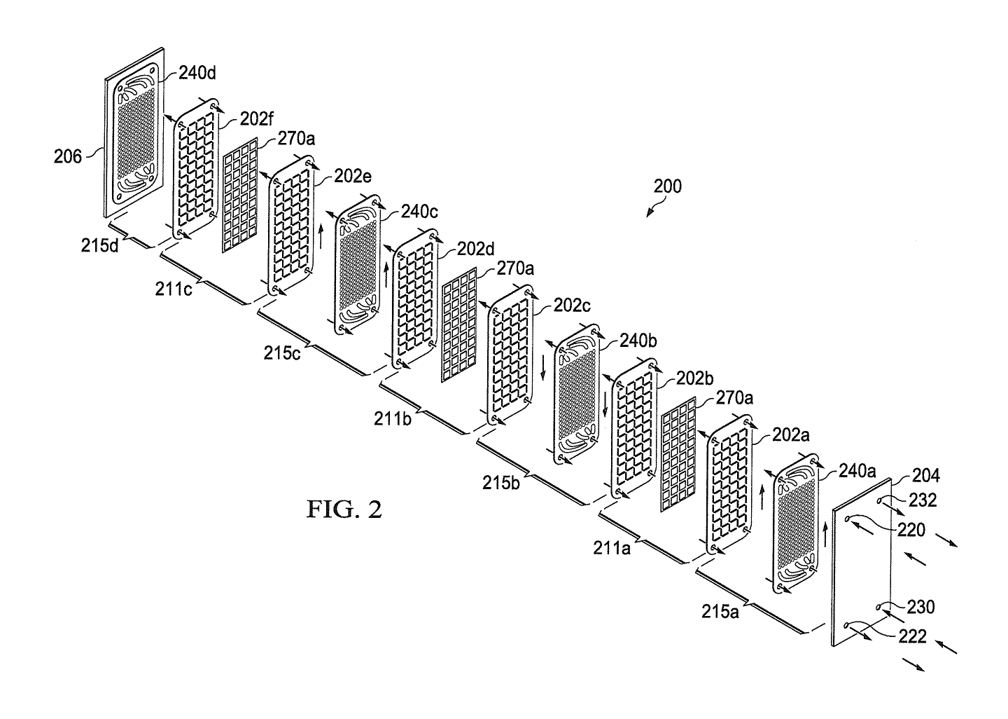

Now turning to FIG. 2, there is illustrated an exploded view of the main components and configuration of a thermoelectric plate heat exchanger (TE-PHE) 200 in accordance with one embodiment of the present disclosure. The TE-PHE 200 includes one or more thermoelectric heat transfer assemblies or modules 210 each having at least one thermoelectric module (TEM) 270. The TEMs 270 may be either a thermoelectric cooler (TEC) or thermoelectric generator (TEG).

Thermoelectric heat transfer devices (commonly and generically referred to as TEMs, and which may be referred to as thermoelectric coolers, heaters or generators, heat pumps, cores or modules) are well-known. These devices are semiconductor-based electronic components that function as a small heat pump.

TEMs function as a heating or cooling device (TECs) by application of a low voltage DC power source. This causes heat to flow via the semiconductor elements from one surface/face to the other. The electric current cools one surface/face and simultaneously heats the opposite surface/face. Consequently, a given surface/face of the device can be used for either heating or cooling by reversing the polarity of the applied power source (current). The characteristics of TECs make them highly suitable for precise temperature control applications and where space limitations and reliability are paramount or refrigerants are not desired. It will be understood that for heating, TECs are significantly more efficient than using conventional resistive heaters.

A typical single stage TEC includes two ceramic plates with “elements” of p-type and n-type semiconductor materials (e.g., bismuth telluride alloys) between the plates. The elements of semiconductor materials are connected electrically in series and thermally in parallel. When a positive DC voltage is applied, electrons pass from the p-type to the n-type element, and the cold-side temperature decreases as the electron current absorbs heat, until equilibrium is reached. Heat absorption (cooling) is proportional to the current and the number of thermoelectric couples. This heat is transferred to the hot side of the cooler, where it is dissipated into a heat sink and/or surrounding environment. These TEC devices use the Peltier effect to create a heat flux between the junctions of two different types of materials. When activated, heat is transferred from one side of the TEC to the other such that a first side/surface of the TEC becomes cold while a second side/surface becomes hot (or vice versa). One example of a TEC that may be used in the TE-PHE 200 for a cooling/heating mode is commercially available from Marlow Industries, Inc., in Dallas, Tex., under the designation RC12-6.

TEMs may also function as thermoelectric generators (TEGs) that generate power (power generation) by utilizing a temperature gradient and heat flow in order to produce useful power output. Direct thermoelectric power generation (direct generation) refers to creation of a heat flow and temperature difference with the primary intent of producing power by TE conversion. Indirect thermoelectric power generation (indirect generation) refers to utilization of a waste or by-product heat flow (generated by some other primary activity) to generate power. TEMs can be useful in direct generation, co-generation, waste heat recovery and energy harvesting applications. One example of a thermoelectric generator (TEG) that may be used in the TE-PHE 200 is commercially available from Marlow Industries, Inc., in Dallas, Tex., under the designation TG12-6.

For heating/cooling and direct/indirect power generation applications, efficiency is important—not only the TEC and TEG efficiency, but also the overall heat transfer efficiency. For power generation applications, high efficiency results from maximizing the temperature difference across the TEG and the average device ZT over that temperature difference.

The TE-PHE 200 includes a plurality of thermally conductive plates 202 positioned adjacent each other and disposed between two outer plates 204, 206. The plates 202a thru 202f are referred to as TEM interface plates. The surfaces of these plates thermally interface with the surfaces of the thermoelectric assemblies or modules 210, and in particular, with each surface of the TEMs 270. As shown in the FIG. 2, the plates 202a and 202b include a first thermoelectric assembly 210a disposed therebetween. Similarly, a second thermoelectric assembly 210b is disposed between the plates 202c and 202d, while a third thermoelectric assembly 210c is disposed between the plates 202e and 202f.

It will be understood the TE-PHE 200 embodiment shown in FIG. 2 is configured with either thermoelectric coolers (TECs) for cooling/heating or thermoelectric generators (TEGs) for power generation. Each of the TE assemblies 210 includes one or more individual TEMs 270, with the TEMs 270 configured as either TECs or TEGs (depending on the mode desired). In the particular embodiment shown, each assembly 210 includes a 4×10 array of TEMs 270. As will be appreciated, any quantity and configuration of TEMs 270 may be included in each TE assembly 210 as suitable for a particular application and desired operating characteristics.

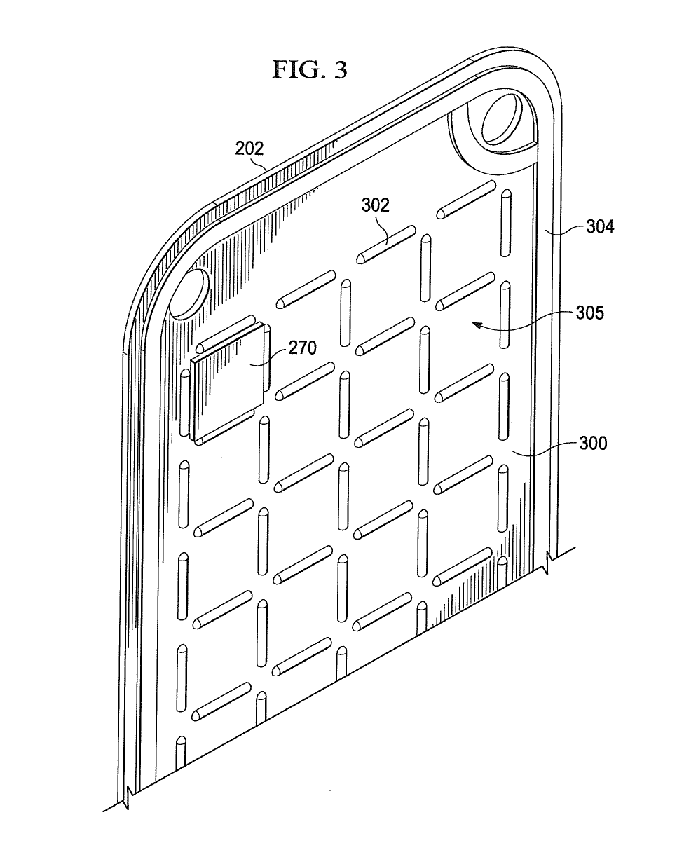

One or more gaskets 304 (shown in FIG. 3) are positioned between each of the plate pairs (202a-202b, 202c-202d, 202e-202f) for sealing an internal volume or chamber 211 (211a, 211b, 211c) between each plate of the plate pairs. Within each of the chambers 211 located between each plate of the TEM interface plate pairs is disposed one of the TE assemblies 210. Other structures or components known to those skilled in the art may be utilized not only for sealing, but also for adhering the plates in a pair to each other, such as epoxy. Additionally, other sealing means or methods may be provided, such as welding, brazing or gluing. However, the use of gaskets or similar non-permanent structures allows for easier disassembly and assembly for manufacturing and/or repair. Any suitable materials may be utilized depending on the particular application, and some example materials may be rubber, synthetic rubber such as Viton® or EPDM, silicon and the like.

As illustrated in FIG. 2, the thermal plate pairs 202a-202b, 202c-202d and 202e-202, with their respective TE assembly 210 therein, are stacked adjacent one another and between the outer plates 204, 206. Though only three plate-pairs with a TE assembly 210 (210a, 210b or 210c) therein are shown, any number of plate-pairs with a TE assembly 210 therein may be utilized. Thus, the present TE-PHE 200 has the added feature of modularity and scalability. Moreover, the TE-PHEs described herein can be manufactured in multiple sizes (e.g., capacity, power output ratings) while using uniform plates 202 having a single size. To increase capacity/size, additional plate-pairs with TE assemblies therein can be added.

By incorporating active thermoelectric devices within a plate heat exchanger, the resulting TE-PHE structure can be more compact, smaller and lighter for a given thermal transfer requirement, or if a given size and weight are generally maintained, a substantial increase in thermal transfer efficiency and capabilities may be obtained.

Interior volumes or chambers 215 are formed between the outer plate 204 and the thermal plate 202a (215a), between the thermal plate 202b and the thermal plate 202c (215b), between the thermal plate 202d and thermal plate 202e (215c), and between the thermal plate 202e and the outer plate 206 (215d).

As shown, the TE-PHE 200 further includes a cold fluid inlet port 220, a cold fluid output port 222, a hot fluid input port 230 and a hot fluid output port 232. Each plate 202 includes apertures corresponding to the ports 220, 222, 230 and 232 for providing cold fluid input, cold fluid output, hot fluid input and hot fluid output channeling.

The plates 202, 204, 206 and ports 220, 222, 230, 232 (and corresponding apertures in the plates 202) are configured to create a first fluid (cold) channel and a second fluid (hot) channel. The cold fluid channel carries a first fluid from the inlet port 220 (cold fluid input channel) through two internal chambers 215b and 215d and to the outlet port 222 (cold fluid output channel). Similarly, the hot fluid channel carries a second fluid from the inlet port 230 (hot fluid input channel) through two internal chambers 215a and 215c and to the outlet port 232 (hot fluid output channel). As the two fluids pass through the chambers 215 within the TE-PHE 200, heat is transferred from one fluid to the other fluid through the TEGs 270. As will be appreciated, gaskets or other structures (not shown) are utilized to configure the path of the two fluid channels between plates.

In the embodiment shown in FIG. 2 (similar to the prior art FIG. 1), the two fluid channels/paths are in a cross-flow configuration. That is, for a channel/path, the inlet and outlet ports are positioned diagonally. In a different embodiment, cross-flow channeling is not utilized. Further, though all four ports are shown positioned at the outer plate 204, all four ports may be positioned at the outer plate 202, or in some combination between the two plates.

Each of the TE assemblies 210 (and each TEM 270) includes a first side (or surface) and a second side (or surface). Herein, the one side (or surface) may be referred to as the “hot side” while the other side (or surface) may be referred to as the “cold side”.

As illustrated by FIG. 2, a first surface (hot side) of the TE assembly 210a is thermally coupled to (and usually physically contacts) a first surface of the thermal TEM interface plate 202a, while a second surface of the thermal TEM interface plate 202a is thermally coupled to (and physically contacts) the hot fluid flowing through the chamber 215a. A second surface of the TE assembly 210a (cold side) is thermally coupled to (and usually physically contacts) a first surface of the thermal TEM interface plate 202b, while a second surface of the thermal TEM interface plate 202b is thermally coupled to (and physically contacts) the cold fluid flowing through the chamber 215b.

A first surface of the TE assembly 210b (cold side) is thermally coupled to (and usually physically contacts) a first surface of the thermal TEM interface plate 202c, while a second surface of the thermal TEM interface plate 202c is thermally coupled to (and physically contacts) the cold fluid flowing through the chamber 215b. A second surface of the TE assembly 210b (hot side) is thermally coupled to (and usually physically contacts) a first surface of the thermal TEM interface plate 202d, while a second surface of the thermal TEM interface plate 202d is thermally coupled to (and physically contacts) the hot fluid flowing through the chamber 215c.

Similarly, a first surface (hot side) of the TE assembly 210c is thermally coupled to (and usually physically contacts) a first surface of the thermal TEM interface plate 202e, while a second surface of the thermal TEM interface plate 202e is thermally coupled to (and physically contacts) the hot fluid flowing through the chamber 215c. A second surface of the TE assembly 210c (cold side) is thermally coupled to (and usually physically contacts) a first surface of the thermal TEM interface plate 202f, while a second surface of the thermal TEM interface plate 202f is thermally coupled to (and physically contacts) the cold fluid flowing through the chamber 215d.

As will be understood by those skilled in the art, a temperature gradient between the hot fluid in chambers 215a and 215c and the cold fluid in chambers 215b and 215d generates a thermal flow in the TEMs 270 which, in turn, generate and output power (in the form of electricity). Though not shown, each of the TEMs 270 includes two (or more) electrical connectors/wires for outputting power (current at a predetermined voltage). As will be appreciated, the electrical connections and wiring of the TEMs within the TE-PHE 200 will be configured (series connections, parallel connections) according to the desired application.

When using TE assemblies 210 and TEMs 270, the particular application or mode for the TE-PHE 200 may be either cooling/heating or power generation. For cooling/heating, TECs will be utilized with input power thereby achieving an increase in the thermal exchange between the two fluids. For power generation, TEGs will be utilized and will generate power from the thermal differential existing between the two fluids. The cooling/heating embodiment is the opposite of the power generation embodiment. Instead of generating and outputting power (power generation) resulting from an existing thermal differential between two fluids, power may be applied which increases the thermal differential between two fluids. For purposes of this patent document, the examples and embodiments herein may be described with respect to cooling/heating (using TECs) or power generation (using TEGs).

Turning now to FIG. 3, there is illustrated a portion of one embodiment of a TEM interface plate 202 in accordance with the present disclosure. The plate 202 includes a first side (or surface) 300 with a plurality of TEM positioning guides 202. The positioning guides 302 function to hold the TEMs 270 in a given position and provide a flat pocket 305 or surface for interfacing with one of the surfaces of the TEM 270. Though illustrated as ridges, in other embodiments, the positioning guides 302 may take any form or shape provided they function to position or hold the TEMs at a predetermined location. The first side 300 of the TEM interface plate 202 is configured to thermally couple (and physically contact) one side of a TEM assembly 210 (and one side of its TEMs 270). Such thermal coupling may be accomplished with any suitable material(s), such as grease, graphite, solder or other thermally conductive material. A gasket 304 is shown around the periphery of the plate 202, which also isolates the apertures in the plate 202 (corresponding to the inlet ports and outlet ports) from the internal chamber resulting in a sealed internal chamber which is fluid proof.

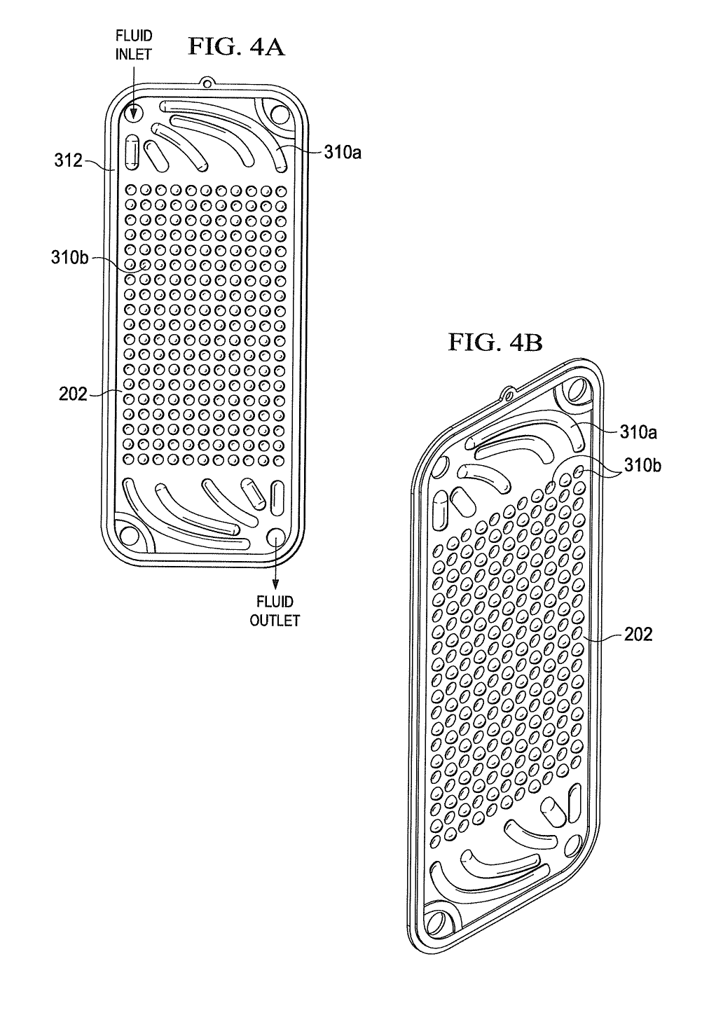

The other side (or surface) of the plate 202 (not readily seen in FIG. 3) contacts fluid. In one embodiment, this side (or surface) is smooth and flat. In another embodiment, one or more turbulence generating structure(s) may be formed in or on that side (or surface) of the plate 202. These may include corrugations (e.g., intermating, chevron), dimples, ridges, channels and the like) which generate turbulence in the fluid flow to increase thermal efficiency. With reference to FIGS. 4A and 4B, there is illustrated the other side (or surface) 306 of the plate 202 having one or more turbulence generating structures 310. These structures are shown as a combination of ridges (or possibly channels) 310a and dimples 310b. A gasket 312 is shown around the periphery of the plate 202, which also isolates the apertures in the plate 202 (corresponding to one fluid's inlet port and outlet port) from the chamber.

The foregoing has described a first embodiment of the TE-PHE 200 which does not include all of the plates shown in FIG. 2. In particular, this first embodiment excludes those additional plates or structures identified by reference numerals 240a, 240b, 240c and 240d. In a second embodiment of the TE-PHE 200, one or more fluid turbulence plates or structures 240a, 240b, 240c and 240d are included within the chambers 215a, 215b, 215c and 215d, respectively, and are configured or structured to generate turbulence as the fluid flows through the chamber(s). The turbulence generating structures 240a, 240b, 240c and 240d are positioned proximate and adjacent to the TEM interface plates 202 and increase thermal transfer efficiency by creating turbulence in the hot and cold fluids.

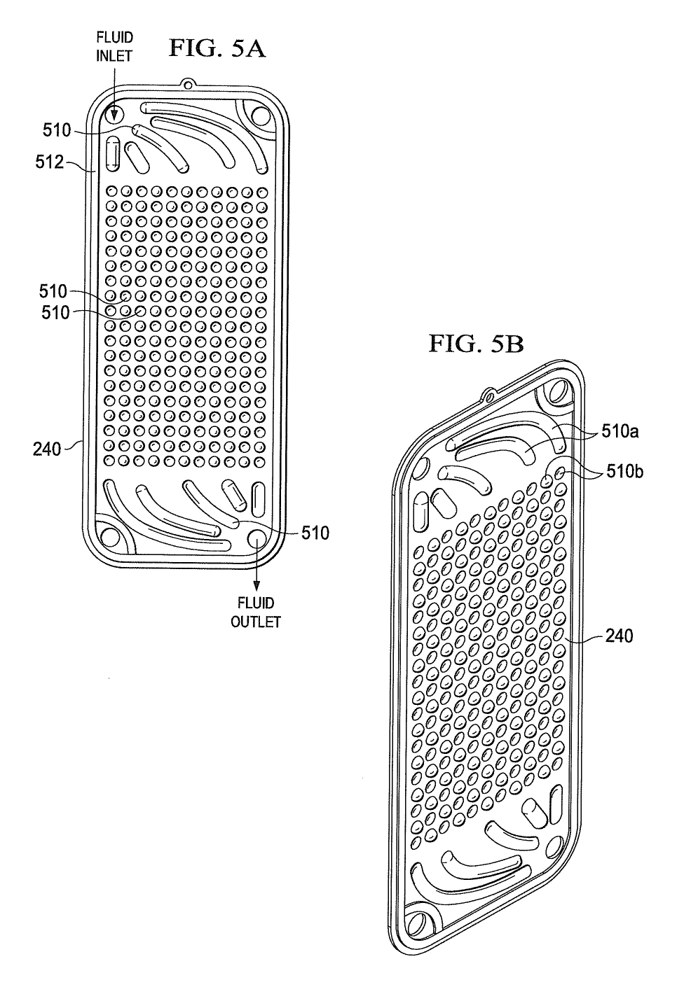

Now turning to FIGS. 5A and 5B, there is illustrated a fluid turbulence plate 240 in accordance with one embodiment of the present disclosure. The plate 240 includes one or more fluid turbulence generating structures 510 on each side (or surface) of the plate 240. These structures 510 are shown as a combination of ridges and valleys 510a and raised dimples and recessed dimples 510b. The dimples 510b promote fluid turbulence, while the ridges/valleys 510a may promote a particular fluid path (and turbulence). Further, the local pattern geometry and density of the dimples 510b may be varied to alter fluid flow path.

As will be appreciated, whether the elements 510a constitute a ridge and/or a valley depends on perspective. In one embodiment, a ridge on one side may also be a valley on the other side, while a raised dimple on one side may be a recessed dimple on the other side. In this embodiment, the plate 240 may be easily manufactured utilizing a stamping process. In another embodiment, a ridge or valley on one side may not have a corresponding valley or ridge on the other side (and the same for raised/recessed dimples). A gasket 512 is shown around the periphery of the plate 240, which also isolates the apertures in the plate 240 (corresponding to one fluid's inlet port and outlet port) from the chamber.

It will also be understood that in the embodiment of the TE-PHE 200, which includes the fluid turbulence generating structures 240a through 240d, the flow chambers identified by reference numerals 215a through 215d are split into two.

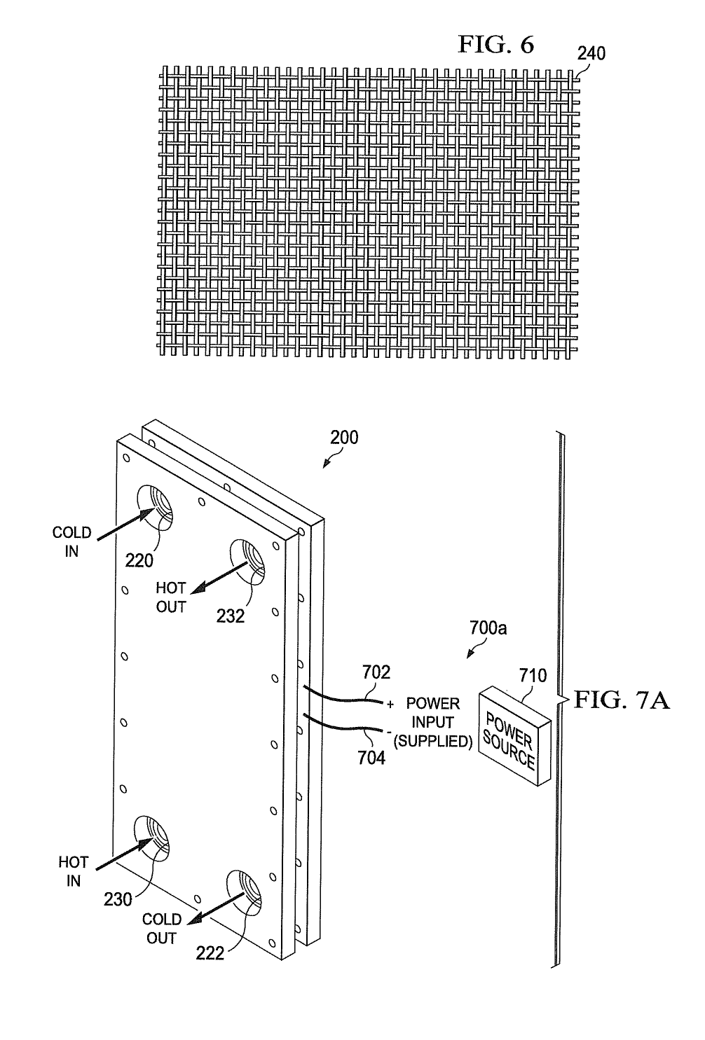

Now turning to FIG. 6, there is illustrated another embodiment of the fluid turbulence structure 240 in accordance with the present disclosure. In this embodiment, the structure 240 is constructed of a thermally conductive mesh, wire cloth, woven wire or wire screen material. Inclusion of a mesh, wire cloth, woven wire or screen material within the fluid flow chamber 215 (215a, 215b, 215c, 215d) creates fluid turbulence which, in turn, increases thermal transfer efficiency. Various types and composition of such materials may be used depending on the particular application and desired operating performance. Suitable thermally conductive mesh, wire cloth, woven wire, or screen material is commercially available from Cleveland Wire Cloth Manufacturing Company, Cleveland, Ohio. Other materials may be steel wool, metal, metal foam, and the like.

In another embodiment, the fluid turbulence structure 240 is constructed or material that has little or no thermal conductivity, such as plastic or foam, which can also be in a matrix/mesh/grid. Use of this type of material may beneficially reduce the weight of the exchanger as opposed to utilizing heavier materials. In either embodiment (conductive or not conductive), the fluid turbulence structure may also assist with increasing thermal transfer efficiency by maintaining compressive integrity within the chambers. In addition, insertion of the structure 240 between the plates assists in creating substantially uniform pressure on all the TEMs 270 (between the plates). In other words, the material creates a gap filling material within the chambers that maintains spacing between adjacent plates enabling the plates to press against the surfaces of the TEMs 270 and generating a crush resistant force as the plates are pressed together during manufacture.

Overall heat transfer coefficients and pressure drops in the TE-PHE 200 can be influenced by varying turbulence structures or plate features. For woven wire, this can be done by altering woven wire count, wire diameter and even shape (circular, triangle, rectangular). In other embodiments, thermally conductive mesh, wire or screen material may be constructed of materials having different wire geometry. For example, a mesh or screen may be weaved with alternating wire geometries to increase turbulence properties. In another embodiment, different areas of the mesh woven wire or screen material may be constructed differently and have different flow rates such that fluid flow in the chamber is altered beneficially.

The TEM interface plates 202 may be constructed of any suitable thermally conductive material or materials, such as copper, aluminum, stainless steel, titanium, nickel, Teflon or any combination of these including alloys. In one embodiment, the thickness of the plates 202 is on the order of 0.020 inches or 0.5 millimeters. The particular material(s) and thickness will likely depend on the fluid composition, operating pressures and other operating conditions in which the exchanger will be utilized. With respect to the outer plates 204, 206, their composition may the same or similar to the plates 202.

Various fluids may be utilized and their composition(s) will depend on the desired application and operating requirements and environment. Suitable fluids may include water, steam, glycol, sea water, oil, and the like. Moreover, the fluid(s) may be single phase or two phase (e.g., steam and water), and the “cold” fluid may be different or the same as the “hot” fluid.

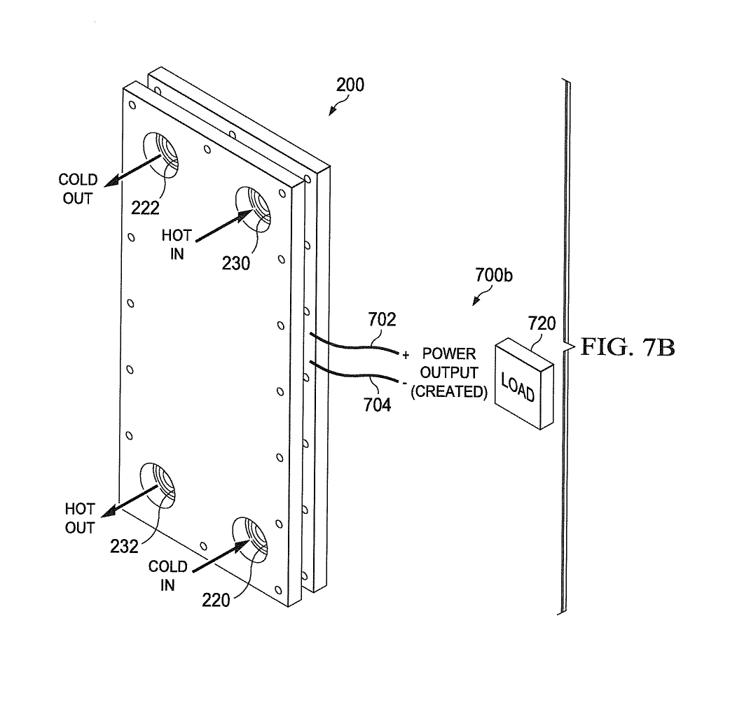

Now turning to FIGS. 7A and 7B, there are illustrated a thermoelectric plate heat exchanger system 700a (in accordance with the present disclosure) in a cooling/heating mode and a thermoelectric plate heat exchanger (in accordance with the present disclosure) system 700b in a power generation application mode.

In system 700a, the TE-PHE 200 is shown with the cold inlet port 220, the cold outlet port 222, the hot inlet port 230 and the hot outlet port 232. In this configuration, the TE-PHE 200 includes one or more TE assemblies 210, each including one or more TEMs 270, and the TEMs are configured as TECs for cooling or heating. The TE-PHE 200 includes at least two electrical conductors or connectors 702, 704 electrically coupled to a power source 710. Depending on the desired application, when the system 700a primary purpose is for cooling, a decrease in the temperature of the cold fluid is desired (for cooling applications). When the primary purpose is for heating, an increase in the temperature of the hot fluid is desired (for heating applications). In either application, the temperature of the cold fluid entering the cold inlet port 220 is greater than the temperature of the cold fluid exiting the cold outlet port 222. Similarly, the temperature of the hot fluid entering the hot inlet port 230 is less than the temperature of the hot fluid exiting the hot outlet port 232.

In operation, the power source 710 is applied across the TEMs 270 within the TH-PHE 200 which, in turn, actively transfers heat from the cold side surface to the hot side surface of the TEMs 270. Therefore, heat is transferred from the cold fluid within the cold fluid chamber through the cold surface to the hot surface and into the hot fluid within the hold fluid chamber.

The power source 710 may include a battery, DC or AC power from a power supply or generator, a supercapacitor, or any other device capable of generating a voltage potential or current flow.

In system 700b, the TE-PHE 200 is shown with the cold inlet port 220, the cold outlet port 222, the hot inlet port 230 and the hot outlet port 232. In this configuration, the TE-PHE 200 includes one or more TE assemblies 210, each including one or more TEMs 270, and the TEMs are configured as TEGs for power generation. The TE-PHE 200 includes at least two electrical conductors or connectors 702, 704 electrically coupled to a load 720. In this mode, the temperature of the cold fluid entering the cold inlet port 220 is less than the temperature of the cold fluid exiting the cold outlet port 222. Similarly, the temperature of the hot fluid entering the hot inlet port 230 is greater than the temperature of the hot fluid exiting the hot outlet port 232.

In operation, the thermal differential between the hot fluid and the cold fluid as applied to the hot side and cold side, respectively, of the TEGs 270, actively generates a voltage potential and current flow in the conductors 702, 704. Thus, the transfer of heat from the hot side to the cold side of the TEGs 270 generates power which is output from the TEGs 270.

The load 720 may include any type of electrical load, such as a battery (for storing energy), an electronic device, or some other device that operates using, or consumes, electrical power.

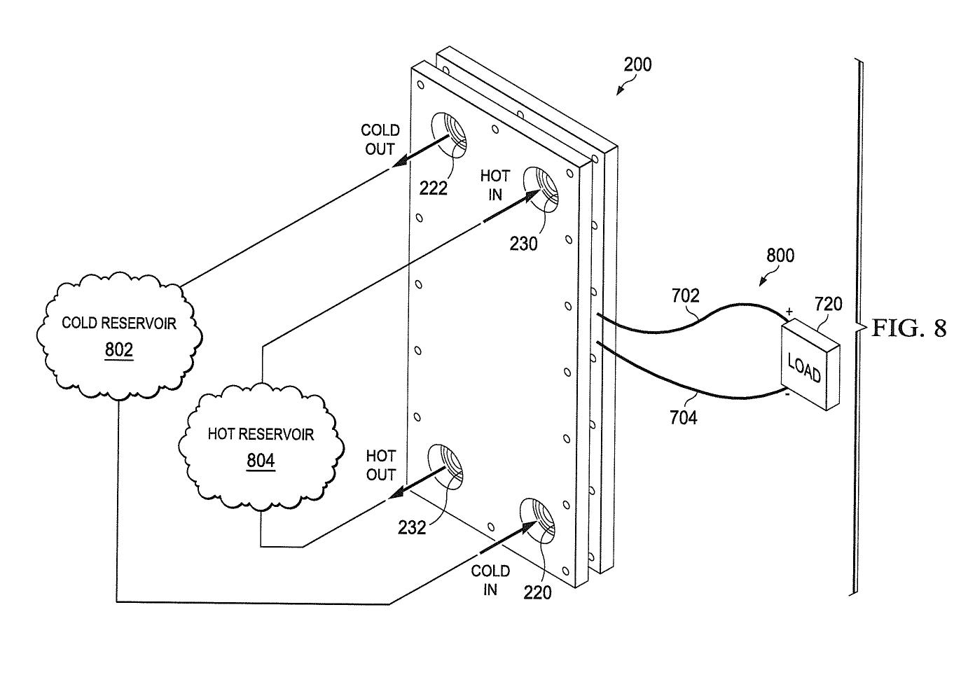

Now turning to FIG. 8, there is illustrated a power generation system 800 that generates electrical power in response to the receiving a cold fluid and a hot fluid.

The system 800 includes the TE-PHE 200 (with TEMs that are TEGs), a first reservoir or tank 802 for holding the cold fluid, a second reservoir or tank 804 for holding the hold fluid, electrical conductors 702, 704 and a load 720 for receiving electrical power from the TE-PHE 200 via the conductors. Various piping or other conduits are provided to transport or deliver cold fluid and hot fluid from the first and second tanks 802, 804, respectively, to the TE-PHE 200 and to transport or receive cold fluid and hot fluid from the TE-PHE 200 to the first and second tanks 802, 804, respectively.

Although the present disclosure has been described with an exemplary embodiment, various changes and modifications may be suggested to one skilled in the art. It is intended that the present disclosure encompass such changes and modifications as fall within the scope of the appended claims.

What is claimed is:

1. A thermoelectric plate exchanger for transferring heat between a first fluid and a second fluid, the thermoelectric plate exchanger comprising:
a first outer plate and a second outer plate;
a first thermally conductive plate adjacent to and spaced apart from the first outer plate, wherein the first thermally conductive plate and the first outer plate define a first fluid flow chamber;
a second thermally conductive plate adjacent to and spaced apart from the second outer plate, wherein the second thermally conductive plate and the second outer plate define a second fluid flow chamber; and
a thermoelectric assembly disposed between, and thermally coupled to, the first thermally conductive plate and the second thermally conductive plate, the thermoelectric assembly comprising one or more thermoelectric devices, each of the one or more thermoelectric devices configured to transfer heat from a first side of the thermoelectric device to a second side of the thermoelectric device when a first fluid is present in the first fluid flow chamber and a second fluid is present in the second fluid chamber and a thermal differential exists between the first fluid and the second fluid.

2. The thermoelectric plate exchanger in accordance with claim 1 further comprising:
a first fluid inlet port;
a first fluid outlet port;
a second fluid inlet port; and
a second fluid outlet port.

3. The thermoelectric plate exchanger in accordance with claim 1 wherein the one or more thermoelectric devices are thermoelectric coolers operable for heating and/or cooling.

4. The thermoelectric plate exchanger in accordance with claim 1 wherein the one or more thermoelectric devices are thermoelectric generators operable for generating power.

5. The thermoelectric plate exchanger in accordance with claim 1 further comprising:
a first structure disposed within the first fluid flow chamber for creating turbulence in fluid flowing through the first fluid flow chamber; and
a second structure disposed within the second fluid flow chamber for creating turbulence in fluid flowing through the second fluid flow chamber.

6. The thermoelectric plate exchanger in accordance with claim 5 wherein the first structure comprises thermally conductive material and the second structure comprises thermally conductive material.

7. The thermoelectric plate exchanger in accordance with claim 6 wherein the thermally conductive material comprises wire mesh material.

8. The thermoelectric plate heat exchanger in accordance with claim 1 wherein the thermoelectric assembly comprises:
a first array of thermoelectric generators disposed between, and thermally coupled to, the first thermally conductive plate and a third thermally conductive plate; and
a second array of thermoelectric generators disposed between, and thermally coupled to, the second thermally conductive plate and a fourth thermally conductive plate.

9. The thermoelectric plate exchanger in accordance with claim 8 wherein the third thermally conductive plate and the fourth thermally conductive plate define a third fluid flow chamber, and the exchanger further comprises:
a first structure disposed within the first fluid flow chamber for creating turbulence in fluid flowing through the first fluid flow chamber;
a second structure disposed within the second fluid flow chamber for creating turbulence in fluid flowing through the second fluid flow chamber; and
a third structure disposed within the third fluid flow chamber for creating turbulence in fluid flowing through the third fluid flow chamber.

10. The thermoelectric plate heat exchanger in accordance with claim 1 wherein the thermoelectric assembly comprises:
a first array of thermoelectric generators disposed between, and thermally coupled to, the first thermally conductive plate and a third thermally conductive plate; and
a second array of thermoelectric generators disposed between, and thermally coupled to, a fourth thermally conductive plate and a fifth thermally conductive plate; and
a third array of thermoelectric generators disposed between, and thermally coupled to, a sixth thermally conductive plate and the second thermally conductive plate.

11. The thermoelectric plate exchanger in accordance with claim 10 wherein the third thermally conductive plate and the fourth thermally conductive plate define a third fluid flow chamber, and the fifth thermally conductive plate and the sixth thermally conductive plate define a fourth fluid flow chamber, and the exchanger further comprises:
a first structure disposed within the first fluid flow chamber for creating turbulence in fluid flowing through the first fluid flow chamber;
a second structure disposed within the second fluid flow chamber for creating turbulence in fluid flowing through the second fluid flow chamber;
a third structure disposed within the third fluid flow chamber for creating turbulence in fluid flowing through the third fluid flow chamber; and
a fourth structure disposed within the third fluid flow chamber for creating turbulence in fluid flowing through the third fluid flow chamber.

12. A thermoelectric plate exchanger comprising:
a first outer plate and a second outer plate;
a first thermally conductive plate adjacent to and spaced apart from the first outer plate, wherein the first thermally conductive plate and the first outer plate define a first fluid flow chamber;
a first means disposed within the first fluid flow chamber for generating fluid turbulence within the first fluid flow chamber when a first fluid flows through the first fluid flow chamber;
a second thermally conductive plate adjacent to and spaced apart from the second outer plate, wherein the second thermally conductive plate and the second outer plate define a second fluid flow chamber;
a second means disposed within the second fluid flow chamber for generating fluid turbulence within the second fluid flow chamber when a second fluid flows through the second fluid flow chamber; and
a thermoelectric assembly disposed between, and thermally coupled to, the first thermally conductive plate and the second thermally conductive plate, the thermoelectric assembly comprising one or more thermoelectric devices each operable for transferring heat from a first side of the thermoelectric device to a second side of the thermoelectric device when a first fluid is present in the first fluid flow chamber and a second fluid is present in the second fluid chamber and a thermal differential exists between the first fluid and the second fluid.

13. The thermoelectric plate exchanger in accordance with claim 12 wherein the first and second means for generating fluid turbulence each comprise:
a thermally conductive turbulence plate having substantially the same dimensions as the first thermally conductive plate.

14. The thermoelectric plate exchanger in accordance with claim 13 wherein the thermally conductive turbulence plate includes one or more turbulence structures formed in or on a surface of the plate.

15. The thermoelectric plate exchanger in accordance with claim 12 wherein the first and second means for generating fluid turbulence each comprise screen material.

16. The thermoelectric plate exchanger in accordance with claim 12 wherein the first and second means for generating fluid turbulence each comprise:
a thermally conductive material including wire.

17. The thermoelectric plate heat exchanger in accordance with claim 12 wherein the thermoelectric assembly comprises:
a first array of thermoelectric generators disposed between, and thermally coupled to, the first thermally conductive plate and a third thermally conductive plate; and
a second array of thermoelectric generators disposed between, and thermally coupled to, a fourth thermally conductive plate and a fifth thermally conductive plate; and
a third array of thermoelectric generators disposed between, and thermally coupled to, a sixth thermally conductive plate and the second thermally conductive plate.

18. The thermoelectric plate exchanger in accordance with claim 17 further comprising:
a third means disposed within a third fluid flow chamber for generating fluid turbulence within the third fluid flow chamber when the first fluid flows through the third fluid flow chamber; and
a fourth means disposed within a fourth fluid flow chamber for generating fluid turbulence within the fourth fluid flow chamber when the second fluid flows through the fourth fluid flow chamber.

19. The thermoelectric plate exchanger in accordance with claim 12 wherein the one or more thermoelectric devices are thermoelectric coolers operable for heating or cooling.

20. The thermoelectric plate exchanger in accordance with claim 12 wherein the one or more thermoelectric devices are thermoelectric generators operable for generating power.

21. A system for generating power from a thermal differential existing between two fluids, the system comprising:
a first fluid reservoir operable for holding a first fluid;
a second fluid reservoir operable for holding a second fluid;
a thermoelectric plate exchanger comprising:
a first outer plate and a second outer plate,
a first thermally conductive plate adjacent to and spaced apart from the first outer plate, wherein the first thermally conductive plate and the first outer plate define a first fluid flow chamber,
a second thermally conductive plate adjacent to and spaced apart from the second outer plate, wherein the second thermally conductive plate and the second outer plate define a second fluid flow chamber, and
a thermoelectric assembly disposed between, and thermally coupled to, the first thermally conductive plate and the second thermally conductive plate, the thermoelectric assembly comprising one or more thermoelectric devices, each of the one or more thermoelectric devices configured to transfer heat from a first side of the thermoelectric device to a second side of the thermoelectric device when the first fluid is present in the first fluid flow chamber and a second fluid is present in the second fluid chamber and a thermal differential exists between the first fluid and the second fluid, and
a first conductor and a second conductor coupled to the thermoelectric assembly and operable for supplying power to a load when a load is coupled to the first and second conductors.

22. The system in accordance with claim 21 wherein the thermoelectric plate exchanger further comprises:
a first fluid inlet port and a first fluid outlet port, both the first fluid inlet and outlet ports coupled to the first fluid reservoir; and
a second fluid inlet port and a second fluid outlet port, both the second fluid inlet and outlet ports coupled to the second fluid reservoir.

23. The system in accordance with claim 21 wherein the thermoelectric plate exchanger further comprises:
a first structure disposed within the first fluid flow chamber for creating turbulence in fluid flowing through the first fluid flow chamber; and
a second structure disposed within the second fluid flow chamber for creating turbulence in fluid flowing through the second fluid flow chamber.

24. The thermoelectric plate exchanger in accordance with claim 23 wherein the first structure comprises a thermally conductive material and the second structure comprises a thermally conductive material.
